(19) United States
(12) Patent Application Publication
(10) Pub. No.: US 2022/0139987 A1
(43) Pub. Date: May 5, 2022

(54) SOLID-STATE IMAGE SENSOR

(71) Applicant: CANON KABUSHIKI KAISHA, Tokyo (JP)

(72) Inventors: Makiko Saito, Tokyo (JP); Hideki Ikedo, Kanagawa (JP)

(21) Appl. No.: 17/576,509

(22) Filed: Jan. 14, 2022

Related U.S. Application Data
(63) Continuation of application No. PCT/JP2020/026057, filed on Jul. 2, 2020.

(30) Foreign Application Priority Data
Jul. 18, 2019 (JP) 2019-133126

(51) Int. Cl. H01L 27/146; H04N 5/374

(52) U.S. Cl. CPC H01L 27/14623; H01L 27/1463; H01L 27/14627; H01L 27/14645; H04N 5/374

(57) ABSTRACT

A solid-state image sensor comprises a first region including a plurality of pixels that each pixel separating portion that intercepts light between the plurality of pixels and shielding each of the pixels from light; a second region provided outside the first region; and light-shielding portion provided in at least a part of a region between the first and second regions, for preventing light from one of the first and second regions from entering the other one, and the light-shielding portion is provided in a semiconductor substrate in which the photoelectric conversion element is provided in a state in which the light-shielding portion extends in the depth direction of the semiconductor substrate, and the light-shielding portion is formed so as to differ in configuration from the pixel separating portion.

### CROSS-REFERENCE TO RELATED APPLICATIONS

This application is a Continuation of International Patent Application No. PCT/JP2020/026057, filed Jul. 2, 2020, which claims the benefit of Japanese Patent Application No. 2019-133126, filed Jul. 18, 2019, both of which are hereby incorporated by reference herein in their entirety.

### BACKGROUND OF THE INVENTION

### Field of the Invention

The present invention relates to the structure of a solid-state image sensor for use in an image-capturing apparatus.

### Background Art

CCD and CMOS image sensors are commonly used as solid-state image sensors in image-capturing apparatuses such as digital cameras. In such image sensors, a plurality of pixels are arrayed in a pixel region of a substrate, and incident light is converted into electric charge and accumulated by photoelectric conversion means, such as a photodiode, that is provided in each pixel.

In order to convert signal electric charge accumulated by photodiodes into voltage signals and output the voltage signals, a CMOS image sensor includes circuit elements such as a pixel transistor in each pixel. There is a problem that pixel sensitivity decreases as a result of the photodiode aperture area being limited by such circuit elements, metal wires such as control signal lines for controlling the circuit elements, a read signal line for extracting a pixel signal, etc.

As a countermeasure against this problem, backside illumination CMOS image sensors, in which photodiodes receive light entering from a surface on the opposite side from the front surface side in which circuit elements and metal wires are disposed, are known. In backside illumination CMOS image sensors, photodiode apertures are not limited by the circuit elements and metal wires, and decrease in sensitivity can thus be suppressed.

On the other hand, there is a problem that the image quality of captured images decreases due to false signals being produced by optical crosstalk, which is a phenomenon in which a light beam entering one pixel with a large inclination enters the photodiode of an adjacent pixel that is different from the pixel without entering the photodiode of the pixel.

As a countermeasure against this problem, PTL 1 discloses an image-capturing apparatus in which light is intercepted between pixels and crosstalk to adjacent pixels is reduced by providing light-shielding portions formed from a light-shielding material such as a resin or a metal next to photodiodes. The amount of false signals produced by optical crosstalk changes depending on incident light amount. It is effective to reduce the ratio of crosstalk amount to incident light amount using the light-shielding portions disclosed in PTL 1 because, inside an aperture region, an amount of crosstalk that is proportional to the amount of incident light entering a pixel of interest affects nearby pixels with incident light amounts close to that of the pixel of interest.

Incidentally, in CCD and CMOS image sensors, the black level of a pixel signal fluctuates due to dark current noise generated while signal electric charge is accumulated. Thus, image-capturing apparatuses are known in which a light-shielding region formed from pixels the light-incident-surface sides of which are shielded from light is provided near an aperture region in which pixels for acquiring an image signal are provided, and optical black (OB) clamping, which is processing in which an image signal is corrected based on dark signals (black level) obtained from the light-shielding region, is performed. In such image-capturing apparatuses, there is a problem that, if high-luminance light enters the aperture region in the vicinity of the light-shielding region, the dark signal level fluctuates due to optical crosstalk from the aperture region to the light-shielding region, and the black level cannot be obtained correctly.

As a countermeasure against this problem, PTL 2 discloses an image-capturing apparatus in which a buffer region that absorbs crosstalk caused by high-luminance light by making use of an absorption characteristic of a semiconductor substrate is provided between an aperture region and a light-shielding region for obtaining dark signals.

### CITATION LIST

### Patent Literature

PTL1: Japanese Patent Laid-Open No. 2010-258157

PTL2: Japanese Patent Laid-Open No. 2000-196055

If false signals caused by crosstalk from the aperture region are produced in the light-shielding region, OB clamping would be performed based on incorrect dark signals, and the entire image signal to be corrected cannot be corrected to the correct level. As discussed above, the amount of false signals produced by optical crosstalk changes depending on incident light amount. Accordingly, the light-shielding region is required to have a light-shielding performance even higher than that required between pixels in the aperture region so that false signals produced in the light-shielding region do not exceed a predetermined tolerance value even if the aperture region in the vicinity of the light-shielding region is irradiated with high-luminance light.

On the other hand, more leaking light can be absorbed and the influence of crosstalk can be reduced by extending the optical path length inside a semiconductor substrate that light entering the semiconductor substrate travels. In view of this, in order to reduce crosstalk, it is effective to widen the buffer region and increase the distance between the aperture region and the light-shielding region as in the conventional technique disclosed in PTL 2. However, the provision of a buffer region that is wide enough to absorb leaking light caused by crosstalk to a sufficient extent would incur an increase in solid-state image sensor chip size and cost.

### SUMMARY OF THE INVENTION

The present invention has been made in view of the above-described problems, and reduces the leaking of light and electric charge between different regions inside a solid-state image sensor while suppressing an increase in chip area.

According to an aspect of the present invention, there is provided a solid-state image sensor comprising: a first region including a plurality of pixels that each include a photoelectric conversion element and receive light from a photographic subject, and pixel separating portion that intercepts light between the plurality of pixels and shielding each of the pixels from light; a second region provided outside the first region; and light-shielding portion provided in at least a part of a region between the first and second regions, for preventing light from one of the first and second regions from entering the other one of the first and second regions, wherein the light-shielding portion is provided in a semiconductor substrate in which the photoelectric conversion element is provided in a state in which the light-shielding portion extends in the depth direction of the semiconductor substrate, and the light-shielding portion is formed so as to differ in configuration from the pixel separating portion.

Further features of the present invention will become apparent from the following description of exemplary embodiments with reference to the attached drawings.

### BRIEF DESCRIPTION OF THE DRAWINGS

The accompanying drawings, which are incorporated in and constitute a part of the specification, illustrate embodiments of the invention and, together with the description, serve to explain principles of the invention.

FIG. 1 is a plan view illustrating the configuration of an image-capturing apparatus according to a first embodiment of the present invention.

FIG. 2 is a plan view illustrating the configuration of a solid-state image sensor in the first embodiment.

FIG. 3 is a cross-sectional view of the solid-state image sensor in the first embodiment.

FIG. 4 is a plan view illustrating the configuration of a solid-state image sensor in a modification of the first embodiment.

FIG. 5 is a cross-sectional view of the solid-state image sensor in the modification of the first embodiment.

FIG. 6 is a cross-sectional view of a solid-state image sensor in a second embodiment.

FIG. 7 is a cross-sectional view of a solid-state image sensor in a third embodiment.

FIG. 8 is a perspective view illustrating the configuration of a solid-state image sensor in a fourth embodiment.

FIG. 9 is a cross-sectional view of the solid-state image sensor in the fourth embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### First Embodiment

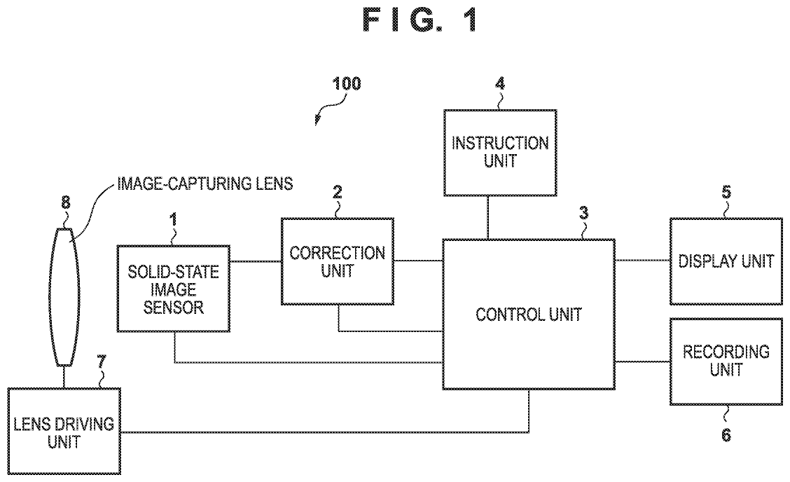

FIG. 1 is a block diagram illustrating the configuration of an image-capturing apparatus 100 in which a solid-state image sensor according to a first embodiment of the present invention is used.

The image-capturing apparatus 100 is formed to include a solid-state image sensor 1, a correction unit 2, a control unit 3, an instruction unit 4, a display unit 5, a recording unit 6, and a lens driving unit 7. Furthermore, the image-capturing apparatus 100 is provided with an image-capturing lens (imaging optical system, lens unit) 8. The image-capturing lens 8 may or may not be detachable from the main body of the image-capturing apparatus. The image-capturing lens 8 forms an optical image of a photographic subject on an imaging surface of the solid-state image sensor 1.

The solid-state image sensor 1 converts the optical image of the photographic subject formed by the image-capturing lens 8 into an imaging signal that is in accordance with the amount of incident light, and outputs the imaging signal. Note that the configuration of the solid-state image sensor 1 will be described in detail later. The correction unit 2 performs predetermined signal processing such as computation processing and correction processing on the imaging signal output from the solid-state image sensor 1, and generates an image signal. The control unit 3 generates and outputs control signals for driving the functional blocks of the image-capturing apparatus 100 based on instructions from the instruction unit 4. Furthermore, the control unit 3 performs predetermined signal processing such as development and compression on the image signal.

Instructions from the outside, such as an instruction to capture an image, user instructions relating to the setting of the drive mode of the image-capturing apparatus 100, etc., are input from the instruction unit 4. The display unit 5 displays the image signal on which signal processing has been performed by the control unit 3, information regarding various settings of the image-capturing apparatus 100, etc.

The recording unit 6 is provided with an unshown recording medium. The recording medium may or may not be detachable from the recording unit 6. The recording unit 6 records, to the recording medium, the image signal on which signal processing has been performed by the control unit 3, etc. Examples of such a recording medium include semiconductor memories such as a flash memory, for example. The lens driving unit 7 is a block that drives the image-capturing lens 8, and performs zoom control, focus control, diaphragm control, etc., in accordance with control signals from the control unit 3.

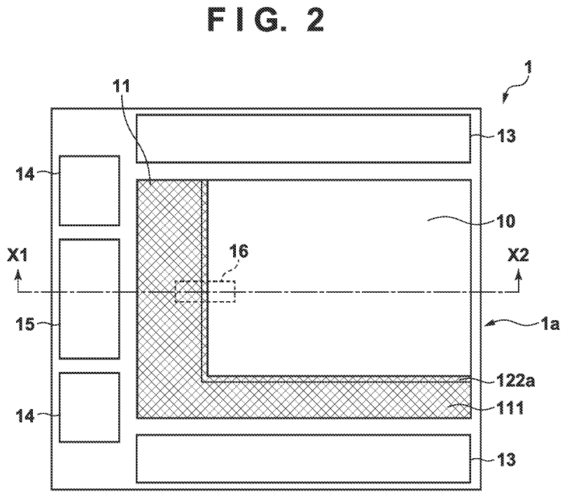

FIG. 2 is a plan view illustrating the configuration of the solid-state image sensor 1 according to the first embodiment.

The solid-state image sensor 1 includes a pixel region 1a in which a plurality of pixels are provided in a matrix. In the present embodiment, the pixel region 1a includes an aperture region 10 and a light-shielding region 11.

In the aperture region 10, which is a first region, a plurality of pixels that include photoelectric conversion elements are provided, and, from each pixel, a signal that is in accordance with the light amount of photographic-subject light entering via the image-capturing lens 8 can be output.

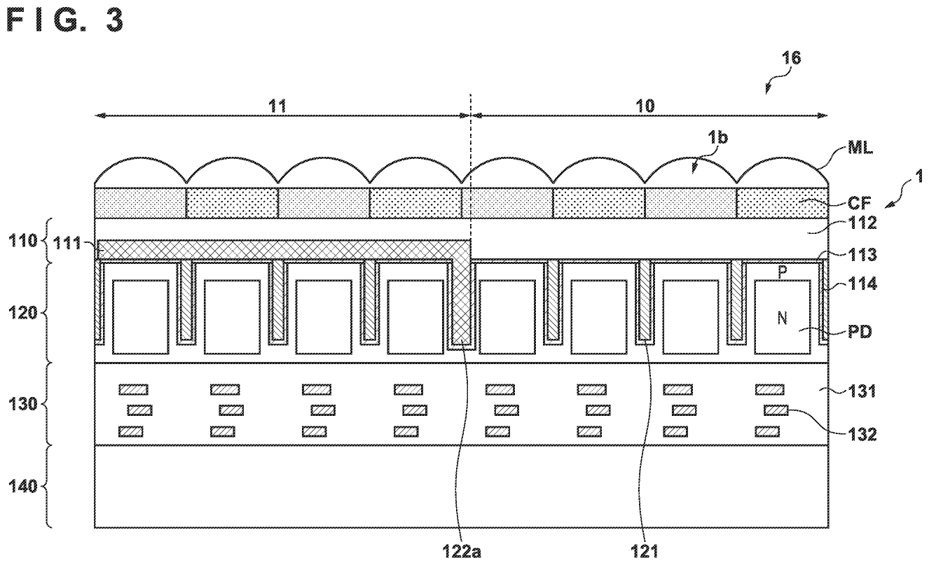

A plurality of pixels that include photoelectric conversion elements are also provided in the light-shielding region 11, which is a second region. However, the light-incident-surface side of each pixel is shielded from light by a light-shielding film 111 (see FIG. 3) that prevents light entering via the image-capturing lens 8 from directly entering each pixel, and a dark state signal that is not dependent on photographic-subject light can be output from each pixel.

Between different regions of the solid-state image sensor 1, namely between the aperture region 10 and the light-shielding region 11 here (between one and the other one of the regions), an inter-region light-shielding wall 122a that is inter-region light-shielding means and prevents light beams entering the solid-state image sensor 1 in an inclined state from entering pixels of the light-shielding region 11 that are near the aperture region 10 is provided.

A signal processing unit 13 processes signals from the pixels of the aperture region 10 and the light-shielding region 11, and outputs the processed signals. For example, the signal processing unit 13 includes one of the following signal processing means: an amplifying circuit that is amplifying means and amplifies voltage signals read from the pixels; and an AD conversion circuit or the like that is converting means and converts voltage signals read from the pixels into digital signal values.

A power supply unit 14 includes a power supply circuit that generates voltages that are necessary for driving the blocks of the solid-state image sensor 1 from an input voltage from the outside, and supplies the generated voltages. A drive signal generation unit 15 generates drive signals for driving circuit elements, and supplies the generated drive signals to blocks, namely the aperture region 10, the light-shielding region 11, and the signal processing unit 13.

FIG. 3 is a cross-sectional view taken along line X1-X2, and illustrates a region 16 of the solid-state image sensor 1 according to the first embodiment, which is illustrated in FIG. 2 and includes the inter-region light-shielding wall 122a, and the aperture region 10 and the light-shielding region 11 in the vicinity of the inter-region light-shielding wall 122a.

The solid-state image sensor 1 includes a plurality of pixels (effective pixels) 1b, and microlenses ML and color filters CF corresponding to the pixels 1b. A light-shielding layer 110 is provided below the microlenses ML and the color filters CF. The light-shielding layer 110 includes the light-shielding film 111, which is light-shielding means and prevents direct entry of light entering via the image-capturing lens 8, in some regions of the solid-state image sensor 1 in a top view. The light-shielding film 111 is at least provided in the light-shielding region 11. A level difference in the thickness direction of the solid-state image sensor 1 that is produced by the light-shielding film 111 is planarized by a planarizing film 112. Note that the above-described microlenses ML and color filters CF need not be provided to the pixels (light-shielding pixels) to which the light-shielding film 111 is provided because such pixels are shielded from photographic-subject light by the light-shielding film 111.

Below the light-shielding layer 110, a semiconductor substrate 120 is provided via pinning films 113 that are formed from hafnium oxide, silicon dioxide, tantalum pentoxide, zirconium dioxide, or the like.

Inside the semiconductor substrate 120, photodiodes PD that are photoelectric conversion elements and correspond to the plurality of pixels 1b are provided in the aperture region 10 and the light-shielding region 11. Pixel separating portions 121 that are pixel separating means are provided between different pixels in order to reduce crosstalk between adjacent pixels. The pixel separating portions 121 are formed by filling groove portions provided in the semiconductor substrate 120 with a light-shielding member, and optically separate adjacent pixels. Here, for example, groove portions provided in the semiconductor substrate 120 from the light-incident-surface side are filled with a light-absorbing material such as silicon dioxide or silicon nitride, and the transmittance of light from one pixel to an adjacent pixel is reduced by absorbing light that enters the pixel but is not absorbed by the pixel. Pinning films 114 are disposed on the surfaces of the pixel separating portions to suppress the leaking of photoelectrically converted electric charge to different pixels. The pinning films 114 may be integrally formed with the pinning films 113. Furthermore, in a case in which the pixel separating portions 121 and the pinning films 114 are formed from the same material, the pixel separating portions 121 and the pinning films 114 are integrally formed.

In addition, inside the semiconductor substrate 120 (in a semiconductor substrate), the inter-region light-shielding wall 122a is provided as inter-region light-shielding means in the light-shielding region 11.

As is the case with the pixel separating portions 121, the inter-region light-shielding wall 122a is formed by filling a groove portion provided in the semiconductor substrate 120 with a light-shielding member from over a pinning film 114. However, the light-shielding member used for filling is varied from that used for the pixel separating portions 121, and a material having lower transmittance is used. For example, the inside of the pinning film 114 is filled with a metal material such as aluminum, copper, or tungsten to reduce the transmittance of light from the aperture region 10 to the light-shielding region 11 to a further extent compared to that between adjacent pixels. For example, with respect to red to infrared light easily propagating through silicon substrates, a light-shielding performance equivalent to that achieved by providing a buffer region having a width of several tens to one hundred and several tens of micrometers in a silicon substrate as in the conventional technique can be achieved by an inter-region light-shielding wall having a width of several tens to one hundred and several tens of nanometers. Note that the leaking of electric charge between the aperture region 10 and the light-shielding region 11 in a silicon substrate may be suppressed to a further extent by forming the pinning film 114 of the inter-region light-shielding wall 122a so as to be thicker than those of the pixel separating portions 121.

In order to perform filling with a metal material as performed for the inter-region light-shielding wall 122a, a groove portion having a greater width than the groove portions for the pixel separating portions 121 is necessary. Widening groove portions in the plane direction of a semiconductor substrate results in pixel apertures being limited, and thus a decrease in pixel sensitivity. Accordingly, in the light-shielding region 11, which is required to have high light-shielding performance, a wide groove portion is formed in a part thereof near the aperture region 10 to form the inter-region light-shielding wall 122a. On the other hand, for the separation of pixels, narrow groove portions are formed to form the pixel separating portions 121, with priority placed on preventing an excessive decrease in sensitivity.

A wiring layer 130 is formed to include, inside an insulating layer 131, wires 132 formed from a metal material such as aluminum, copper, or tungsten. Via the wires 132, drive signals are supplied from the drive signal generation unit 15 to the pixels, and read signals are transmitted from the pixels to the signal processing unit 13. Furthermore, a support substrate 140 is provided below the wiring layer 130. Note that photographic-subject light enters the solid-state image sensor 1 from the surface (upper side in the drawing) on the opposite side from the surface (lower side in the drawing) in which the wiring layer 130 is arranged. The solid-state image sensor 1 in the present embodiment has a configuration as described above.

Dark signals read from the pixels in the light-shielding region 11 are used to correct signals read from the pixels in the aperture region 10. For example, in OB clamping correction performed by the correction unit 2, the dark signals obtained from the pixels in the light-shielding region 11 are used as reference signals to correct the levels of the signals obtained from the pixels in the aperture region 10.

By arranging the inter-region light-shielding wall 122a close to the aperture region 10-side end portion of the light-shielding region 11, the region from which correct dark output cannot be obtained due to the penetration of light from the aperture region 10 can be reduced. For example, in FIG. 3, an example is illustrated in which the inter-region light-shielding wall 122a is provided between a pixel in an end portion of the aperture region 10 and a pixel in an end portion of the light-shielding region 11. However, the sensitivity of the aperture region 10-side pixel that is adjacent to the inter-region light-shielding wall 122a may change depending on the reflectance of the inter-region light-shielding wall 122a.

Accordingly, a configuration may be adopted such that the signal from the aperture region 10-side effective pixel that is adjacent to the inter-region light-shielding wall 122a is not used for the generation of the image signal. Alternatively, a configuration may be adopted such that the inter-region light-shielding wall 122a is provided at a position that is located further inward in the light-shielding region 11 from the edge of the light-shielding film 111 by one to several pixels, and one to several light-shielding pixels are present on the aperture region 10 side of the inter-region light-shielding wall 122a. In this case, it suffices not to use the light-shielding pixels on the aperture region 10-side of the inter-region light-shielding wall 122a for the correction of the image signal. In a solid-state image sensor in which the pixel pitch is several micrometers, for example, the width of the unused region can be significantly reduced compared to a case in which a buffer region having a width of several tens to one hundred and several tens of micrometers is provided in a silicon substrate as in the conventional technique, even if an effective pixel or light-shielding pixels near the inter-region light-shielding wall 122a is/are not used in such a manner. Note that a configuration may be adopted such that signal reading is not performed for unused pixels, to reduce the overall amount of time required to read signals from the solid-state image sensor 1 and improve frame rate.

As described above, the solid-state image sensor in the present embodiment is configured such that inter-region light-shielding means that is provided with lower transmittance than pixel separating means by using a light-shielding member that is different from that used for the pixel separating means is provided in a light-shielding region outside an aperture region. According to the present embodiment, the necessary light-shielding performance can be achieved with a smaller area compared to a conventional buffer region that uses an absorption characteristic of a semiconductor substrate to absorb optical crosstalk from an aperture region to a light-shielding region.

Accordingly, in a solid-state image sensor, the leaking of light and electric charge between different regions inside the solid-state image sensor can be reduced while suppressing an increase in chip area.

### Modification of First Embodiment

The solid-state image sensor 1 illustrated in FIG. 2 includes circuit elements such as the signal processing unit 13, the power supply unit 14, the drive signal generation unit 15, and MOS transistors. If a leak occurs as a result of such circuit elements operating, and the light emitted thereby propagates through the inside of the substrate to enter the photodiodes in the pixel region 1a, which includes the light-shielding region 11 and the aperture region 10, the light produces noise. In the present embodiment, an inter-region light-shielding wall 122b is provided between the pixel region 1a and the circuit blocks 13 to 15 other than the pixel region in order to reduce such noise caused by the circuit elements outside the pixel region emitting light.

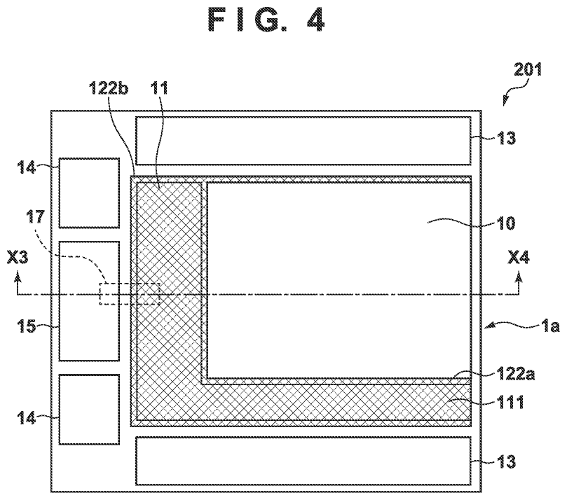

The configuration of a solid-state image sensor 201 in the present modification will be described below. FIG. 4 is a plan view illustrating the configuration of the solid-state image sensor 201 in the present modification. As illustrated in FIG. 4, the solid-state image sensor 201 includes circuit blocks such as the signal processing unit 13, the power supply unit 14, and the drive signal generation unit 15 in a third region that is different from the first region, in which the aperture portion 10 is provided, and the second region, in which the light-shielding region 11 is provided. The signal processing unit 13, the power supply unit 14, and the drive signal generation unit 15 include circuit elements, such as MOS transistors, that do not constitute unit pixels.

Between each circuit block arranged in the third region mentioned above and the aperture region 10/light-shielding region 11, the inter-region light-shielding wall 122b, which is inter-region light-shielding means and prevents light produced in the third region from entering the pixels in the light-shielding region 11 and the aperture region 10, is provided. The rest of the configurations are similar to those in the first embodiment.

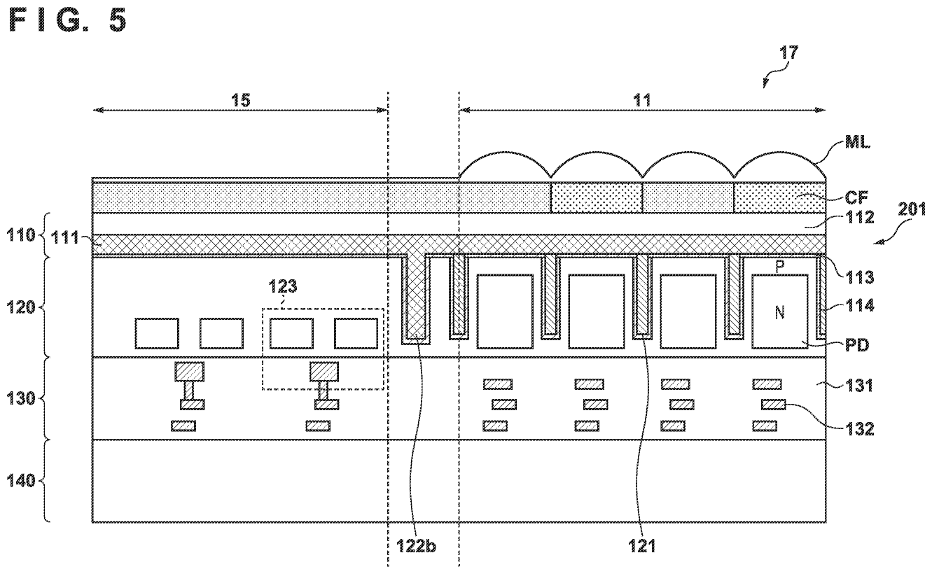

FIG. 5 is a cross-sectional view taken along line X3-X4, and illustrates a region 17 of the solid-state image sensor 201 in the present modification, which is illustrated in FIG. 4 and includes the inter-region light-shielding wall 122b, the light-shielding region 11, which is the pixel region in the vicinity of the inter-region light-shielding wall 122b, and the drive signal generation unit 15 arranged in the third region.

Inside the semiconductor substrate 120, a plurality of MOS transistors 123 are provided in the third region, in which the drive signal generation unit 15 is provided, and the third region is shielded from light by the light-shielding film 111. Furthermore, inside the semiconductor substrate 120, the inter-region light-shielding wall 122b is provided as inter-region light-shielding means between the pixel region 1a and the circuit blocks provided in the third region. Here, a state in which the inter-region light-shielding wall 122b is provided between the light-shielding region 11 and the drive signal generation unit 15 is illustrated.

As is the case with the inter-region light-shielding wall 122a, the inter-region light-shielding wall 122b is formed by filling a groove portion provided in the semiconductor substrate 120 with a light-shielding member having lower transmittance than the pixel separating portions 121. For example, the inter-region light-shielding wall 122b is filled with a metal material such as aluminum, copper, or tungsten to reduce transmittance of light from the third region to a further extent compared to that between adjacent pixels. Note that the light-shielding region 11 has a configuration similar to that in the first embodiment.

As described above, the solid-state image sensor in the present modification is configured such that inter-region light-shielding means that is provided with lower transmittance than pixel separating means by using a light-shielding member that is different from that used for the pixel separating means is provided between a pixel region and circuit blocks other than the pixel region. According to the present modification, the penetration of light and electric charge into the pixel region from circuit blocks outside the pixel region can be reduced by means of the inter-region light-shielding means.

Second Embodiment

The configuration of a solid-state image sensor according to a second embodiment of the present invention will be described below. The present embodiment differs from the first embodiment in that an inter-region light-shielding wall 122c is provided in place of the inter-region light-shielding wall 122a in the configuration of the solid-state image sensor 1 according to the first embodiment. In the following, description will be provided focusing on the differences from the first embodiment, and description regarding configurations that are similar to those in the first embodiment will be omitted as appropriate.

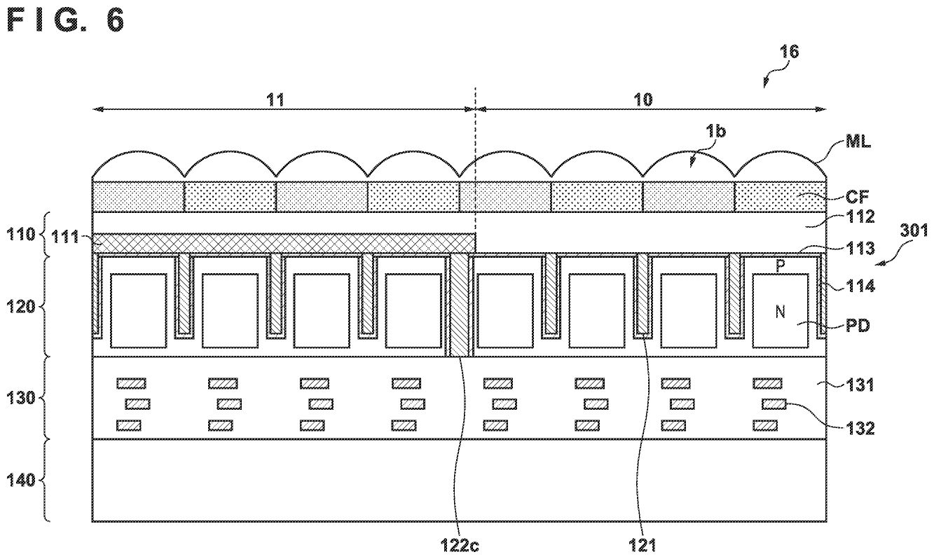

FIG. 6 is a cross-sectional view taken along line X1-X2, and illustrates the region 16 of a solid-state image sensor 301 in the second embodiment, which includes the inter-region light-shielding wall 122c provided in place of the inter-region light-shielding wall 122a illustrated in FIG. 2, and the aperture region 10 and the light-shielding region 11 in the vicinity of the inter-region light-shielding wall 122c.

Inside the semiconductor substrate 120, the inter-region light-shielding wall 122c is provided as inter-region light-shielding means in the light-shielding region 11. As is the case with the pixel separating portions 121, the inter-region light-shielding wall 122c is formed by filling a groove portion provided in the semiconductor substrate 120 with a light-shielding member from over a pinning film 114. However, the shape of the inter-region light-shielding wall 122c is varied from that of the pixel separating portions 121 to make the transmittance of the inter-region light-shielding wall 122c even lower. For example, the transmittance of light from the aperture region 10 to the light-shielding region 11 is reduced to a further extent compared to that between adjacent pixels by providing a groove portion that is wider and that is deeper (that extends deeper) than the pixel separating portions 121 and thereby increasing the width and depth filled by the light-shielding member. Note that, here, the effect of suppressing leaking of electric charge is also improved because the surface area of the pinning film 114 is enlarged due to the depth of the inter-region light-shielding wall 122c being increased.

As described above, the solid-state image sensor in the present embodiment is configured such that inter-region light-shielding means that is provided with lower transmittance than pixel separating means by varying the shape thereof from that of the pixel separating means is provided in a light-shielding region outside an aperture region. According to the present embodiment, the necessary light-shielding performance can be achieved with a smaller area compared to the buffer region according to the conventional technique.

Accordingly, the leaking of light and electric charge between different regions inside a solid-state image sensor can be reduced while suppressing an increase in chip area.

### Third Embodiment

The configuration of a solid-state image sensor according to a third embodiment of the present invention will be described below.

The present embodiment differs from the first embodiment in that a plurality of inter-region light-shielding walls 122d are provided in place of the inter-region light-shielding wall 122a in the configuration of the solid-state image sensor 1 according to the first embodiment. In the following, description will be provided focusing on the differences from the first embodiment, and description regarding configurations that are similar to those in the first embodiment will be omitted as appropriate.

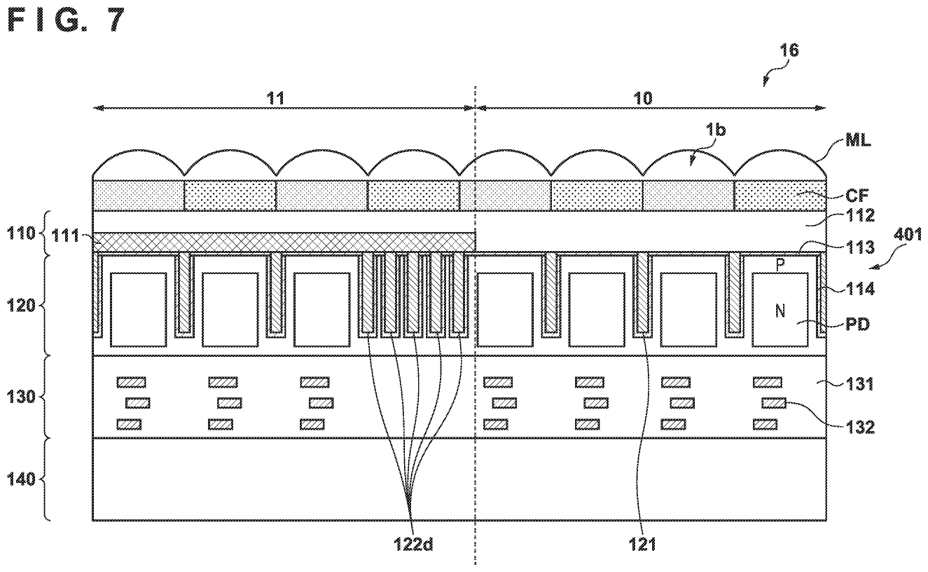

FIG. 7 is a cross-sectional view taken along line X1-X2, and illustrates the region 16 of a solid-state image sensor 401 according to the third embodiment, which includes the inter-region light-shielding walls 122d provided in place of the inter-region light-shielding wall 122a illustrated in FIG. 2, and the aperture region 10 and the light-shielding region 11 in the vicinity of the inter-region light-shielding walls 122d.

Inside the semiconductor substrate 120, the inter-region light-shielding walls 122d are provided as inter-region light-shielding means in the light-shielding region 11. As is the case with the pixel separating portions 121, the inter-region light-shielding walls 122d are formed by filling groove portions provided in the semiconductor substrate 120 with a light-shielding member from over pinning films 114. By continuously providing such inter-region light-shielding walls 122d, the transmittance of light from the aperture region 10 to the light-shielding region 11 is reduced to a further extent compared to that between adjacent pixels. Note that, here, the effect of suppressing leaking of electric charge is also improved because a plurality of pinning films 114 are also provided due to a plurality of inter-region light-shielding walls 122d being provided.

Since the area necessary for providing a plurality of inter-region light-shielding walls 122d is larger compared to that necessary for providing a pixel separating portion 121, a configuration may be adopted, as illustrated in FIG. 7, in which no photodiode is provided in a region corresponding to one to several pixels in the light-shielding region 11, for example, and the inter-region light-shielding walls 122d are provided in place thereof

By providing the inter-region light-shielding walls 122d with the same shape as the pixel separating portions 121 and using the same filling material as that used for the pixel separating portions 121 for the inter-region light-shielding walls 122d, the inter-region light-shielding walls 122d can be formed in the same manufacturing process as that in which the pixel separating portions 121 are formed when manufacturing the solid-state image sensor 401. Manufacturing steps can thus be simplified. Alternatively, by varying the filling material used for the inter-region light-shielding walls 122d from that used for the pixel separating portions 121, the transmittance of the plurality of inter-region light-shielding walls 122d can be reduced to a further extent.

As described above, the solid-state image sensor in the present embodiment is configured such that a plurality of inter-region light-shielding walls are provided in a light-shielding region outside an aperture region and provided with lower transmittance than pixel separating means. According to the present embodiment, the necessary light-shielding performance can be achieved with a smaller area compared to the buffer region according to the conventional technique.

Accordingly, the leaking of light and electric charge between different regions inside a solid-state image sensor can be reduced while suppressing an increase in chip area.

### Fourth Embodiment

The configuration of a solid-state image sensor according to a fourth embodiment of the present invention will be described below.

In the present embodiment, a configuration is adopted in which the blocks in the configuration of the solid-state image sensor 1 according to the first embodiment are separately arranged using a plurality of substrates, and the plurality of substrates are laminated together. In the following, description will be provided focusing on the differences from the first embodiment, and description regarding configurations that are similar to those in the first embodiment will be omitted as appropriate.

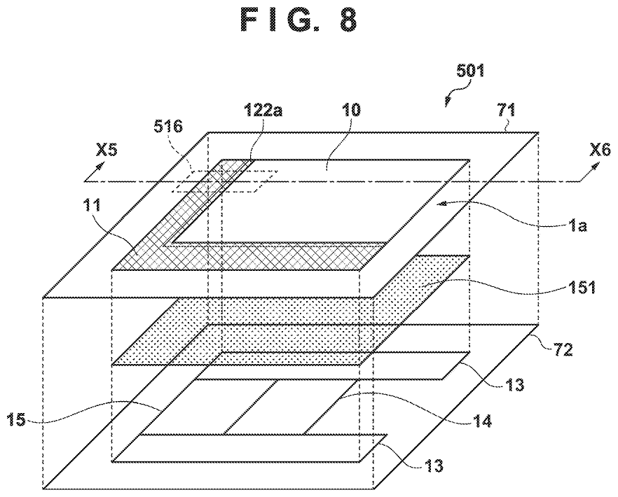

FIG. 8 is a perspective view illustrating the configuration of a solid-state image sensor 501 in the fourth embodiment.

The solid-state image sensor 501 has a configuration in which a first substrate 71 and a second substrate 72 are laminated. The first substrate 71 is provided with blocks including the pixel region 1a. The pixel region 1a includes the aperture region 10 and the light-shielding region 11, and as is the case in the first embodiment, the inter-region light-shielding wall 122a, which is inter-region light-shielding means, is provided between the aperture region 10 and the light-shielding region 11.

The second substrate 72 is provided with at least some of the circuit blocks other than the pixel region. Here, a configuration is adopted in which the second substrate 72 is provided with the signal processing unit 13, the power supply unit 14, and the drive signal generation unit 15.

Between the first substrate 71 and the second substrate 72, an inter-substrate light-shielding portion 151 that is inter-substrate light-shielding means and prevents light produced by the circuit elements provided to the second substrate 72 from entering the pixels of the first substrate 71 is provided. The inter-substrate light-shielding portion 151 extends so as to include at least a region on which the pixel region and circuit blocks other than the pixel region are arranged when the first substrate 71 and the second substrate 72 are laminated.

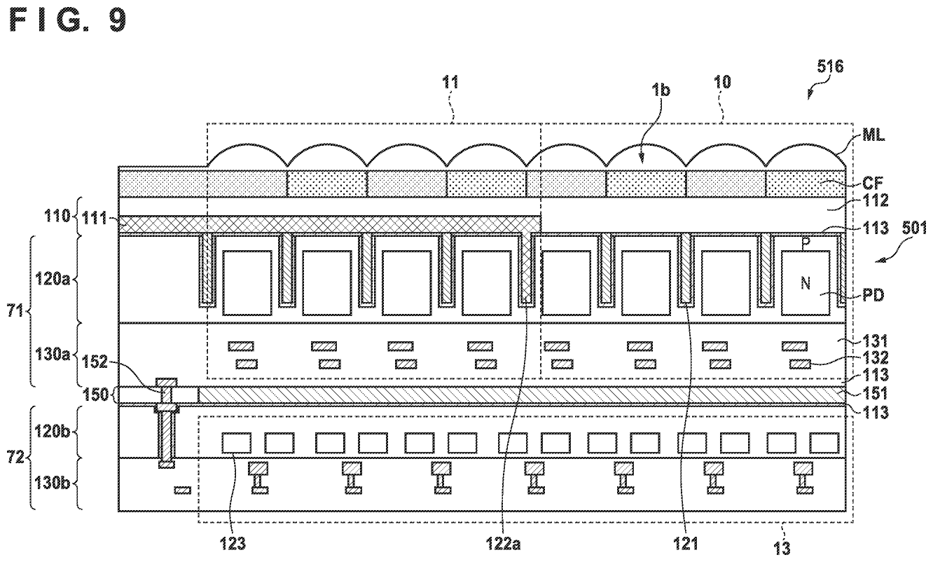

FIG. 9 illustrates a cross-section taken along line X5-X6 of a region 516 of the solid-state image sensor 501 illustrated in FIG. 8 that includes the inter-region light-shielding wall 122a provided to the first substrate 71, and the aperture region 10 and the light-shielding region 11 in the vicinity of the inter-region light-shielding wall 122a, and a cross-section of the signal processing unit 13 of the second substrate 72 laminated to the bottom part of the region 516.

The first substrate 71 includes a wiring layer 130a and a semiconductor substrate 120a including photodiodes PD corresponding to the pixels. Inside the semiconductor substrate 120a, the inter-region light-shielding wall 122a is provided as inter-region light-shielding means in the light-shielding region 11. The second substrate 72 includes a wiring layer 130b and a semiconductor substrate 120b including circuit elements 123 constituting circuit blocks other than the pixel region 1a.

The first substrate 71 and the second substrate 72 are laminated via an inter-substrate connection layer 150. The wires in the wiring layer 130a of the first substrate 71 and the wires in the wiring layer 130b of the second substrate 72 are electrically connected to one another by an inter-substrate connection portion 152 provided in the inter-substrate connection layer 150.

In the inter-substrate connection layer 150, the inter-substrate light-shielding portion 151 is provided so as to include a region to which the pixel region of the first substrate 71 and the circuit blocks provided to the second substrate 72 (the signal processing circuit 13 here) are laminated. The inter-substrate light-shielding portion 151 is formed from a metal material such as aluminum, copper, or tungsten, or a light-absorbing material such as silicon dioxide or silicon nitride.

Note that, while an example in which the inter-substrate light-shielding portion 151 is provided in the inter-substrate connection layer 150 is described here, the inter-substrate light-shielding portion 151 may be provided in the wiring layer 130a of the first substrate 71. Furthermore, in a case in which the second substrate 72 is laminated to the first substrate 71 in a state in which the front and back sides of the second substrate 72 are reversed, the inter-substrate light-shielding portion 151 may be provided in the wiring layer 130b of the second substrate 72.

As described above, the solid-state image sensor in the present embodiment is configured such that inter-region light-shielding means that is provided with lower transmittance than pixel separating means is provided in a light-shielding region outside an aperture region. Furthermore, inter-substrate light-shielding means is provided to as to include a region to which a pixel region and circuit blocks other than the pixel region are laminated when a substrate including the pixel region and a substrate including the circuit blocks other than the pixel region are laminated. According to the present embodiment, the penetration of light into the pixel region from circuit blocks outside the pixel region can be reduced.

Accordingly, the leaking of light and electric charge between different regions inside a solid-state image sensor can be reduced while suppressing an increase in chip area.

As described above, in the first to fourth embodiments, light-shielding means that differs in configuration from pixel separating means is provided between an aperture region or a light-shielding region of a solid-state image sensor and another region of the solid-state image sensor. Thus, a solid-state image sensor in which the light-shielding performance between regions is improved as compared to the light-shielding performance between pixels can be provided.

According to the present invention, the leaking of light and electric charge between different regions inside a solid-state image sensor can be reduced while suppressing an increase in chip area.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)TM), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A solid-state image sensor comprising:
a first region including a plurality of pixels that each include a photoelectric conversion element and receive light from a photographic subject, and pixel separating portion that intercepts light between the plurality of pixels and shielding each of the pixels from light;
a second region provided outside the first region; and
light-shielding portion provided in at least a part of a region between the first and second regions, for preventing light from one of the first and second regions from entering the other one of the first and second regions,
wherein the light-shielding portion is provided in a semiconductor substrate in which the photoelectric conversion element is provided in a state in which the light-shielding portion extends in the depth direction of the semiconductor substrate, and the light-shielding portion is formed so as to differ in configuration from the pixel separating portion.

2. The solid-state image sensor according to claim 1, wherein the second region includes a light-shielding pixel that is shielded from light so that light from a photographic subject does not enter the light-shielding pixel.

3. The solid-state image sensor according to claim 1, wherein the first region further includes a light-shielding pixel that is shielded from light so that light from a photographic subject does not enter the light-shielding pixel, and the second region includes a circuit element that does not constitute the pixels.

4. The solid-state image sensor according to claim 3, wherein the light-shielding portion prevents light produced by the circuit element from entering the first region.

5. The solid-state image sensor according to claim 3, wherein the second region includes, as the circuit element, at least one of signal processor that processes signals from the pixels, controller that supplies control signals to the pixels or the signal processor, and power supplier that supplies power to the pixels, the signal, or the controller.

6. The solid-state image sensor according to claim 1, wherein the depth to which the light-shielding portion extends in the depth direction of the semiconductor substrate differs from the depth to which the pixel separating portion extends in the depth direction of the semiconductor substrate.

7. The solid-state image sensor according to claim 6, wherein the depth to which the light-shielding portion extends in the depth direction of the semiconductor substrate is deeper than the depth to which the pixel separating portion extends in the depth direction of the semiconductor substrate.

8. The solid-state image sensor according to claim 1, wherein the material for forming the light-shielding portion differs from the material for forming the pixel separating portion.

9. The solid-state image sensor according to claim 8, wherein the material for forming the light-shielding portion has lower transmittance than the material for forming the pixel separating portion.

10. The solid-state image sensor according to claim 1, wherein the width of the light-shielding portion in the plane direction of the semiconductor substrate differs from the width of the pixel separating portion in the plane direction of the semiconductor substrate.

11. The solid-state image sensor according to claim 10, wherein the width of the light-shielding portion in the plane direction of the semiconductor substrate is wider than the width of the pixel separating portion extends in the plane direction of the semiconductor substrate.

12. The solid-state image sensor according to claim 1, wherein the number in which the light-shielding portion is provided differs from the number in which the pixel separating portion is provided.

13. The solid-state image sensor according to claim 12, wherein the number in which the light-shielding portion is provided is more than the number in which the pixel separating portion is provided.

14. The solid-state image sensor according to claim 1, wherein a pixel adjacent to the light-shielding portion does not include the photoelectric conversion element.

15. The solid-state image sensor according to claim 1, wherein the semiconductor substrate includes a wiring layer in which wires that transmit signals from the pixels are arranged, and light from a photographic subject enters the pixels from a surface on the opposite side from a surface including the wiring layer.
